(19) United States
(12) Patent Application Publication
(10) Pub. No.: US 2009/0209071 A1
(43) Pub. Date: Aug. 20, 2009

(54) METHODS OF MANUFACTURING SEMICONDUCTOR DEVICES

(75) Inventors: Moon-Sook Lee, Seoul (KR); Byeong-Ok Cho, Seoul (KR); Man-Hyoung Ryoo, Gyeonggi-do (KR); Takahiro Yasue, Gyeonggi-do (KR)

Correspondence Address: MYERS BIGEL SIBLEY & SAJOVEC, PO BOX 37428, RALEIGH, NC, 27627, US

(73) Assignee: Samsung Elecronics Co., Ltd.

(21) Appl. No.: 12/388,012

(22) Filed: Feb. 18, 2009

(30) Foreign Application Priority Data
Feb. 18, 2008 (KR) 10-2008-0014479

(51) Int. Cl. H01L 21/8238

(52) U.S. Cl. 438/210; 438/478; 977/762; 977/938; 257/E21.632

(57) ABSTRACT

First nanowires and second nanowires are alternately disposed and spaced apart on a first substrate in a second direction that is parallel to an adjacent major surface of the first substrate. Each of the first and second nanowires extends in a first direction that is perpendicular to the second direction, and the first and second nanowires are doped with first and second conductive types, respectively. A plurality of gate lines are formed that are at least partially disposed within the first substrate, that are spaced apart in a third direction, that extend in a fourth direction that is perpendicular to the third direction, and that partially enclose the first and second nanowires

### CROSS REFERENCE TO RELATED APPLICATION

This application claims priority under 35 USC § 119 to Korean Patent Application No. 2008-14479, filed on Feb. 18, 2008 in the Korean Intellectual Property Office (KIPO), the contents of which are herein incorporated by reference in their entirety.

### BACKGROUND

1. Field

Example embodiments relate to semiconductor devices and methods of manufacturing semiconductor devices. More particularly, example embodiments relate to semiconductor devices having nanowire channels and related methods of manufacturing such devices.

2. Description of the Related Art

Silicon has been mainly used as a channel material of a transistor. However, according to the type of transistor, optimum materials for the channel may be varied. For example, when germanium is used as a channel material of a p-channel metal-oxide-semiconductor (PMOS) transistor, the PMOS transistor may have enhanced characteristics, and when gallium arsenide (GaAs) is used as a channel material of an n-channel MOS (NMOS) transistor, the NMOS transistor may have enhanced characteristics.

When a complementary MOS (CMOS) transistor is formed, in order to form channels using optimum materials for the specific types of transistors, not a single process but a plurality of processes is needed to be performed. For example, a CMOS transistor may be formed by forming a germanium layer on a silicon substrate by an epitaxial growth process and forming a gallium arsenide (GaAs) layer on the germanium layer by an epitaxial growth process. However, the above method requires fastidious conditions such as low pressure and high temperature, and different material layers are needed to be stacked on each other, and thus many difficult fabrication problems may occur.

### SUMMARY

Various embodiments are directed to semiconductor devices having nanowire channels which may have optimum channel materials, while some other embodiments are directed to methods of manufacturing such semiconductor devices.

According to some example embodiments, a method of manufacturing a semiconductor device includes alternately disposing first nanowires and second nanowires on a first substrate that are spaced apart in a second direction that is parallel to an adjacent major surface of the substrate. Each of the first and second nanowires extends in a first direction that is perpendicular to the second direction, and the first and second nanowires are doped with first and second conductivity type dopants, respectively. A plurality of gate lines are formed that are at least partially disposed within the first substrate, that are spaced apart in a third direction, that extend in a fourth direction that is perpendicular to the third direction, and that partially enclose the first and second nanowires

In a further embodiment, portions of the first and second nanowires may be partially removed to form a plurality of first nanowire patterns and a plurality of second nanowire patterns, respectively. The gate lines may partially enclose the first and second nanowire patterns.

In a further embodiment, a plurality of unit cells are defined on the first substrate. Each of the unit cells includes a plurality of the first and second nanowire patterns spaced apart in the second direction.

In a further embodiment, a plurality of the unit cells are disposed in the fourth direction to define a unit cell column, and a plurality of the unit cell columns are spaced apart in the third direction to define a unit cell array.

In a further embodiment, a bitline is formed that is electrically connected to the unit cells within each of the unit cell columns. A plurality of capacitors are formed that are electrically connected to the unit cells, respectively. For example, each of the capacitors may be electrically connected to a different one of the unit cells.

In a further embodiment, a plurality of bitline contacts are formed that electrically connect the bitline to the unit cells. A plurality of capacitor contacts are formed that electrically connect the capacitors to the unit cells, respectively. For example, each of the capacitor contacts may electrically connect a capacitor to a unit cell.

In a further embodiment, a plurality of first ohmic layers are formed that directly contact the bitline contacts, respectively, and extend to directly contact the first and second nanowire patterns in each unit cell. A plurality of second ohmic layers are formed to directly contact the capacitor contacts, respectively, and extend to directly contact the first and second nanowire patterns, respectively, in each unit cell.

In a further embodiment, a gate insulation layer may be further formed on each of the first and second nanowires.

In a further embodiment, the gate insulation layer may be formed prior to disposing the first and second nanowires on the first substrate.

In a further embodiment, the third direction may be the same as the second direction.

In a further embodiment, the third direction may make an acute angle with the first direction.

In a further embodiment, the first conductive type may be formed as a p-type and the second conductive type may be formed as an n-type.

In a further embodiment, the first nanowires may be formed to include germanium and the second nanowires may be formed to include gallium arsenide (GaAs).

In a further embodiment, the first and second nanowires may be grown by applying catalyst particles onto second and third substrates and depositing a nanowire source gas onto the second and third substrates. The first and second nanowires can then be moved to be alternately disposed on the first substrate spaced apart in the second direction.

In a further embodiment, a plurality of trenches can be formed spaced apart on the first substrate in the fourth direction and extending in the third direction. The gate lines may be formed within and to fill the trenches.

In a further embodiment, when the first and second nanowires are alternately disposed on the first substrate, the first nanowires may be disposed on the first substrate spaced apart in the second direction, and the second nanowires may be disposed on the first substrate spaced apart in the second direction in spaces between adjacent pairs of the first nanowires.

Some other example embodiments are directed to providing a semiconductor device. The semiconductor device includes a first nanowire pattern including a plurality of first nanowires spaced apart in a second direction on a substrate, a second nanowire pattern including a plurality of second nanowires spaced apart in the second direction on the substrate, and a gate line on the substrate. The first nanowire pattern is doped with a first conductivity type dopant. The first nanowire pattern extends in a first direction parallel to an adjacent major surface of the substrate and that is perpendicular to the first direction. The second nanowire pattern is doped with a second conductivity type dopant and formed on the substrate. Each of the second nanowires of the second nanowire pattern is disposed between adjacent pairs of first nanowires of the first nanowire pattern. The gate line partially encloses the first and second nanowire patterns and extends in a third direction.

In a further embodiment, a unit cell includes the first and second nanowire patterns. A plurality of the unit cells may be disposed in a fourth direction that is perpendicular to the third direction to form a unit cell column.

In a further embodiment, the semiconductor device may further include a bitline and a plurality of capacitors. The bitline may be commonly electrically connected to the unit cells within each unit cell column, and the capacitors may be electrically connected to the unit cells, respectively.

In a further embodiment, the semiconductor device may further include a gate insulation layer between the first and second nanowire patterns and the gate line.

In a further embodiment, the third direction may be the same as the second direction.

In a further embodiment, the third direction may make an acute angle with the first direction.

In a further embodiment, the first conductivity type dopant may be a p-type and the second conductivity type dopant may be an n-type.

In a further embodiment, the first nanowire pattern may include germanium and the second nanowire pattern may include gallium arsenide (GaAs).

In a further embodiment, the semiconductor device may further include a trench extending in the third direction on the substrate. The gate line may be within and fill the trench.

According to some embodiments, nanowires having different conductive types are formed using optimum materials for channels and are alternately disposed on a substrate. Gate structures, bitlines and capacitors are also formed. The semiconductor devices may thereby have improved channel characteristics and/or may be more easily manufactured.

### BRIEF DESCRIPTION OF THE DRAWINGS

Example embodiments will be more clearly understood from the following detailed description taken in conjunction with the accompanying drawings. FIGS. 1 to 25 represent non-limiting, example embodiments as described herein.

FIGS. 1 to 5, FIGS. 10 to 12, and FIGS. 14 to 15 are perspective views illustrating methods of manufacturing semiconductor devices in accordance with some example embodiments;

FIGS. 6 to 9 are plan views illustrating methods of manufacturing semiconductor devices in accordance with some example embodiments;

FIGS. 13 and 16 are cross-sectional views illustrating methods of manufacturing semiconductor devices in accordance with some example embodiments;

FIGS. 17 and 20 are perspective views illustrating methods of manufacturing semiconductor devices in accordance with other example embodiments;

FIG. 18 is an enlarged view of first and second nanowires 34 and 35 in FIG. 17;

FIG. 19 is a plan view illustrating methods of manufacturing semiconductor devices in accordance with other example embodiments;

FIGS. 21, 24 and 25 are perspective views illustrating methods of manufacturing semiconductor devices in accordance with still other example embodiments; and

FIGS. 22 and 23 are plan views illustrating methods of manufacturing semiconductor devices in accordance with still other example embodiments.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

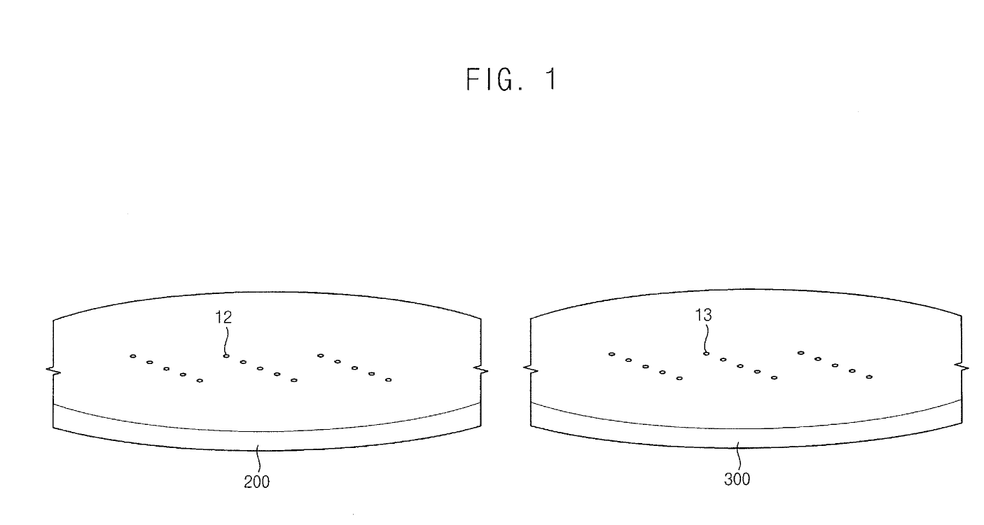

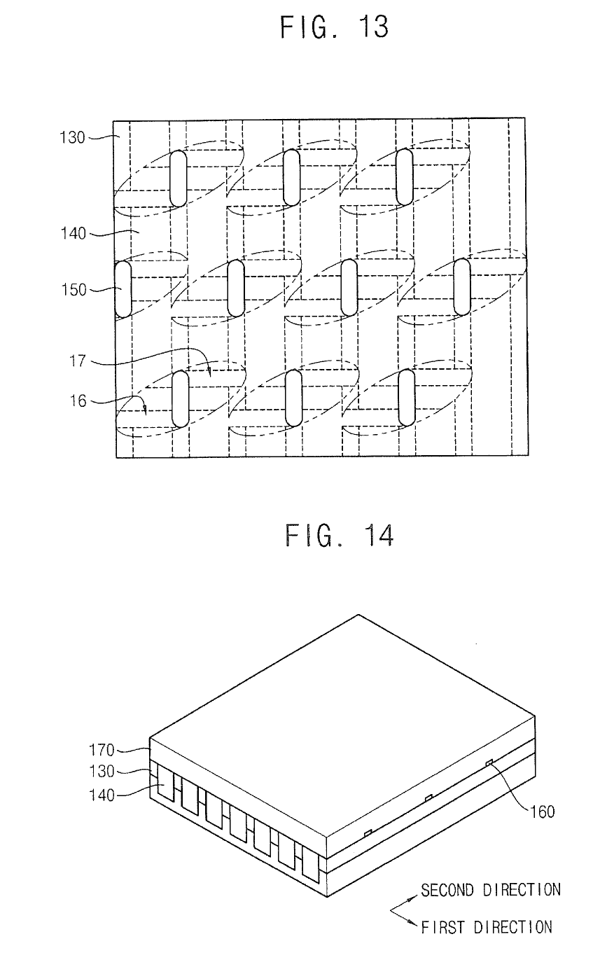

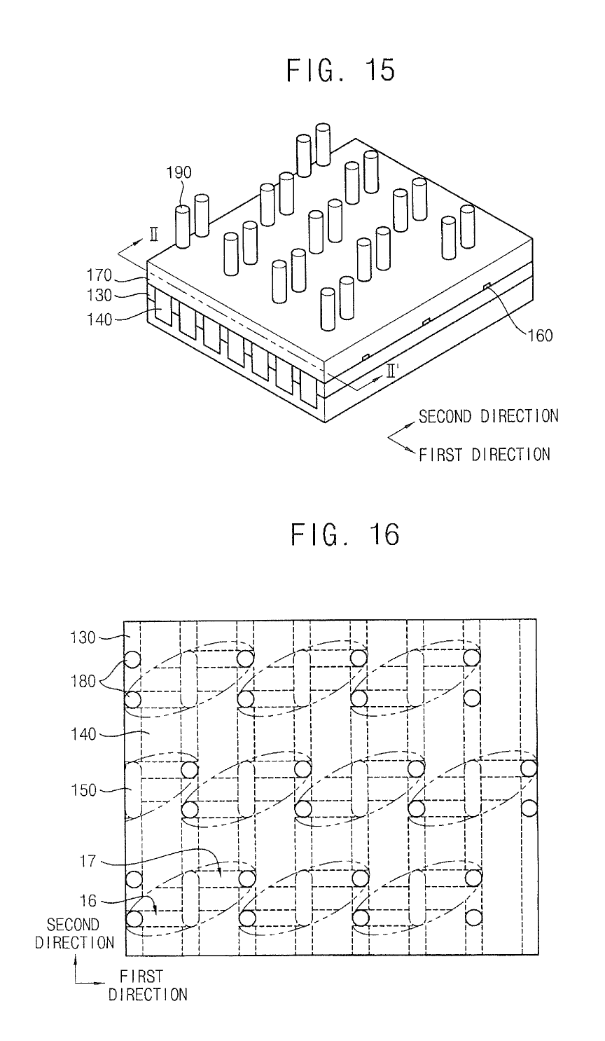

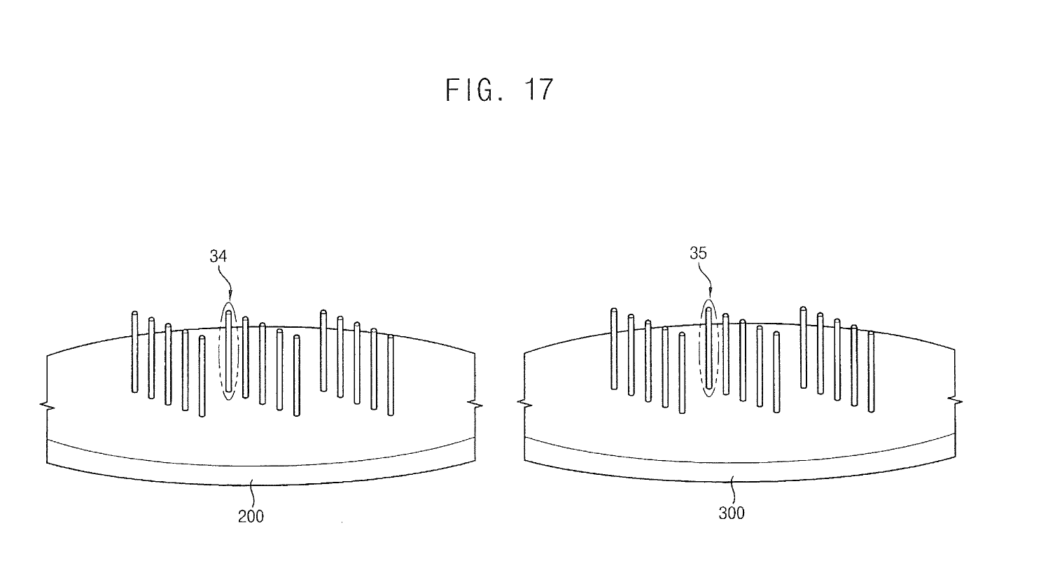

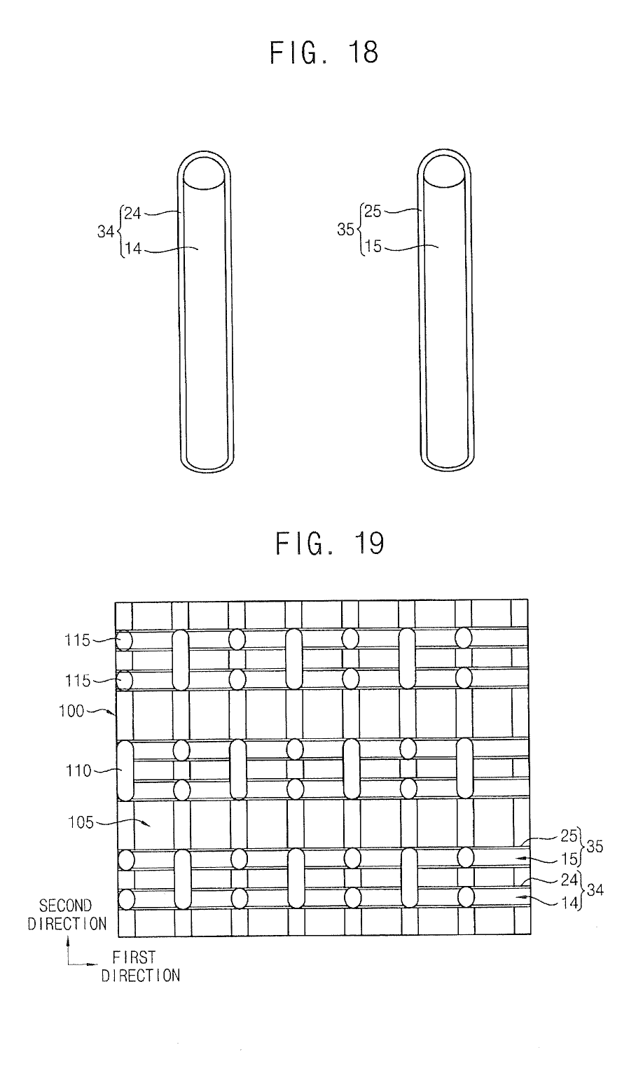

FIGS. 1 to 5, FIGS. 10 to 12, and FIGS. 14 to 15 are perspective views illustrating methods of manufacturing semiconductor devices in accordance with some example embodiments. FIGS. 6 to 9 are plan views illustrating methods of manufacturing semiconductor devices in accordance with some example embodiments. FIGS. 13 and 16 are cross-sectional views illustrating methods of manufacturing semiconductor devices in accordance with some example embodiments. Particularly, FIG. 13 is a cross-sectional view of the semiconductor device in FIG. 12 taken along the line I-I′, and FIG. 16 is a cross-sectional view of the semiconductor device in FIG. 15 taken along the line II-II′.

Referring to FIG. 1, a plurality of first catalyst particles 12 is applied onto a second substrate 200, and a plurality of second catalyst particles 13 is applied onto a third substrate 300.

The second and third substrates 200 and 300 may include a semiconductor material such as silicon or germanium, or may include an insulating material such as an oxide or a nitride.

Each of the first and second catalyst particles 12 and 13 has a diameter of about several nanometers, and may include a metal. For example, the first and second catalyst particles 12 and 13 may include gold, nickel, cobalt, aluminum, etc. The first and second catalyst particles 12 and 13 may be applied onto the second and third substrates 200 and 300, respectively, by an imprint method, a lift-off method or a photo-etch method.

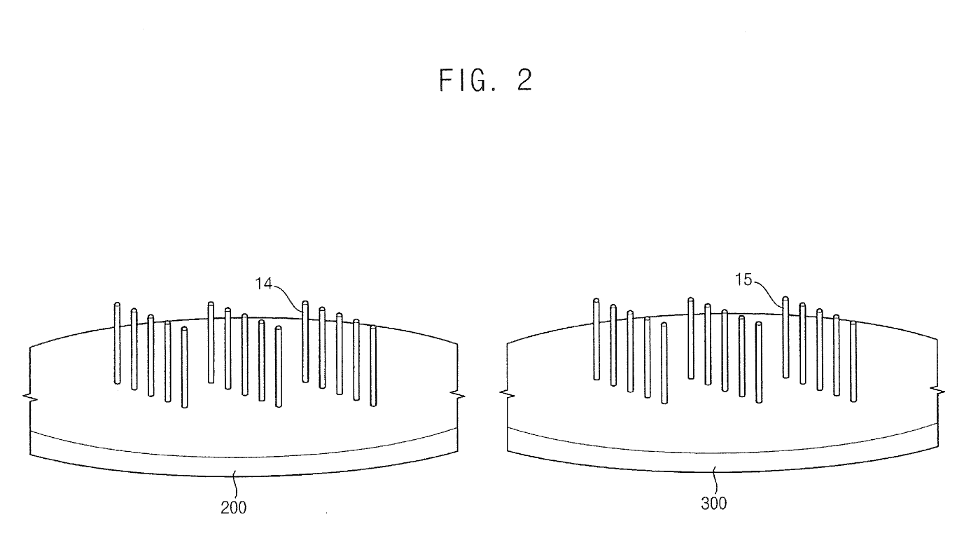

Referring to FIG. 2, a chemical vapor deposition (CVD) process using a nanowire source gas is performed to grow a plurality of first nanowires 14 and a plurality of second nanowires 15 at positions where the first and second catalyst particles 12 and 13 are formed, respectively. In one example embodiment, the first and second nanowires 14 and 15 are grown in directions perpendicular to the second and third substrates 200 and 300, respectively. In another example embodiment, the first and second nanowires 14 and 15 may be grown in random directions that are not perpendicular to the second and third substrates 200 and 300, respectively. Each of the first and second nanowires 14 and 15 may have a circular cross-sectional area. Alternatively, each of the first and second nanowires 14 and 15 may have a polygonal cross-sectional area such as a rectangular cross-sectional area, a hexagonal cross-sectional area or an octagonal cross-sectional area.

A silicon source gas such as silane (SiH4), tetrachlorosilane (SiCl4), etc., a germanium source gas such as germane (GeH4), germanium tetrachloride (GeCl4), etc., or a gallium arsenide source gas such as triethylgallium (Ga(C2H5)3), arsine (AsH3), etc. may be used as the nanowire source gas. Accordingly, the first and second nanowires 14 and 15 may grow to be semiconductor nanowires including silicon, germanium and/or gallium arsenide. Materials used for forming the first and second nanowires 14 and 15 are not limited to the above materials, and group IV elements of the periodic table or compounds of group III elements and group V elements, which have good channel characteristics, may be also used for forming the first and second nanowires 14 and 15. In an example embodiment, the first nanowires include germanium and the second nanowires include gallium arsenide. The first nanowires 14 may be doped with p-type impurities using p-type impurity source gas such as diborane (B2H6), and the second nanowires 15 may be doped with n-type impurities using n-type impurity source gas such as phosphine (PH3).

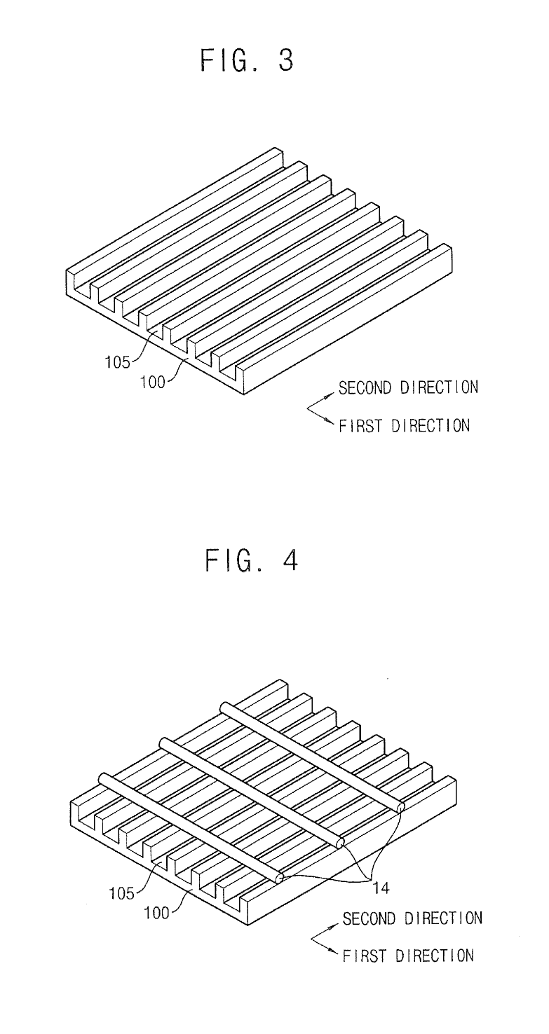

Referring to FIG. 3, a first substrate 100 including an insulating material such as an oxide or a nitride is prepared.

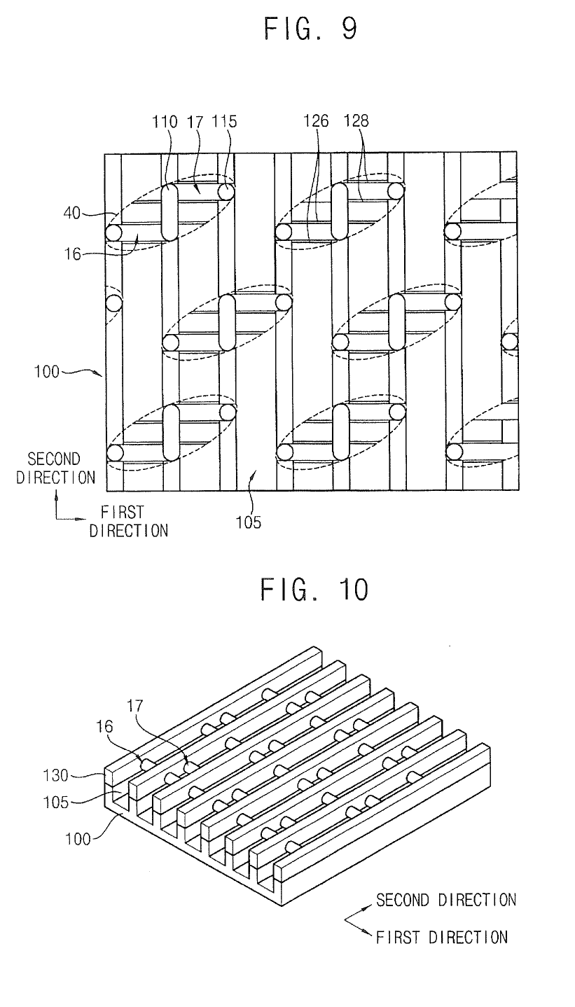

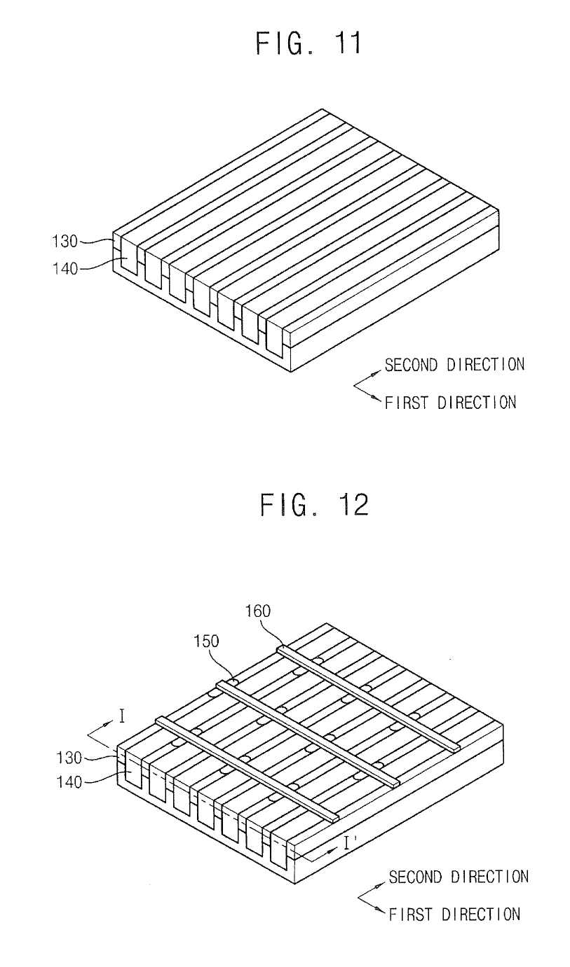

In an example embodiment, a plurality of trenches 105 each of which extends in a second direction is formed on the first substrate 100 in a first direction perpendicular to the second direction. The trenches 105 will be filled with gate lines 140 (see FIG. 11) later, and gate structures may enclose gate insulation layer patterns 126 and 128 (see FIG. 8 or FIG. 9) and nanowire patterns 16 and 17 (see FIGS. 8 to 10). Thus, a gate-all-around (GAA) type semiconductor device may be manufactured. Alternatively, the trenches 105 may not be formed, and in this case, the gate structures may partially enclose the gate insulation layer patterns 126 and 128 and the nanowire patterns 16 and 17 in an Ω-shape.

Referring to FIG. 4, the first nanowires 14 on the second substrate 200 are moved to be spaced apart on the first substrate 100. In an example embodiment, the first nanowires 14 each of which extends in the first direction are spaced apart in the second direction. Thus, each first nanowire 14 is disposed perpendicularly not only to each trench 105 but also to each gate line 140 that will be later formed in each trench 105.

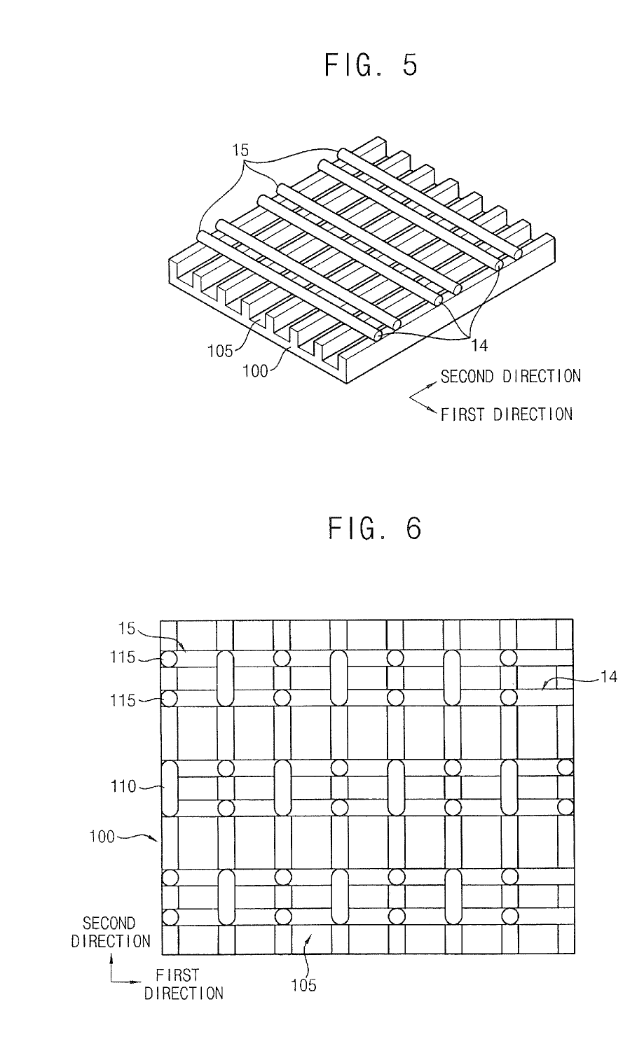

Referring to FIG. 5, the second nanowires 15 on the third substrate 300 are moved to be disposed on the first substrate 100. In an example embodiment, the second nanowires 15 each extend in the first direction and are spaced apart in the second direction between different adjacent pairs of the first nanowires 14. Thus, the first and second nanowires 14 and 15 may be spaced apart in the second direction on the first substrate 100 in an alternating sequence to provide a first nanowire 14, a second nanowire 15, a first nanowire 14, a second nanowire 15, and so on. Like the first nanowires 14, each second nanowire 15 may be disposed perpendicularly not only to each trench 105 but also to each gate line 140 that will be later formed in each trench 105.

Accordingly, the first nanowires 14 may all be disposed on the first substrate 100 before the second nanowires 15 are disposed on the first substrate 100. Alternatively, the first and second nanowires 14 and 15 may be alternately disposed on the first substrate 100.

Referring to FIG. 6, a first ohmic layer 110 and a second ohmic layer 115 are formed on the first and second nanowires 14 and 15.

The first ohmic layer 110 may be formed on a couple of adjacent first and second nanowires 14 and 15 and the first substrate 100, and the second ohmic layer 115 may be formed on each of the first and second nanowires 14 and 15. In an example embodiment, the first and second ohmic layers 110 and 115 are formed on or over top portions of the first substrate 100 in which the trenches 105 are not formed. The first ohmic layer 110 may make direct contact with a first bitline contact 150 (see FIG. 12), and the second ohmic layer 115 may make direct contact with a first capacitor contact 180 (see FIG. 16). Thus, the first and second ohmic layers 110 and 115 may be electrically connected to a first bitline 160 (see FIG. 12) and a first capacitor 190 (see FIG. 15), respectively.

In an example embodiment, a plurality of the first ohmic layers 110 and a plurality of the second ohmic layers 115 are formed. Particularly, the first and second ohmic layers 110 and 115 are formed alternately in the first direction. Additionally, the first ohmic layers 110 and a couple of the second ohmic layers 115 may be formed alternately in the second direction.

The first and second ohmic layers 110 and 115 may be formed to include a metal silicide by applying a metal such as cobalt, nickel, etc. onto the first and second nanowires 14 and 15 or onto the first substrate 100 and performing a heat treatment thereon. The metal may be applied onto the first and second nanowires 14 and 15 or onto the first substrate 100 by a stamping process such as a nano-imprint process or a nano-transfer printing process. The first and second ohmic layers 110 and 115 are formed using the metal silicide, thereby having ohmic characteristics with the first bitline contact 150 or with the first capacitor contact 180 including a metal.

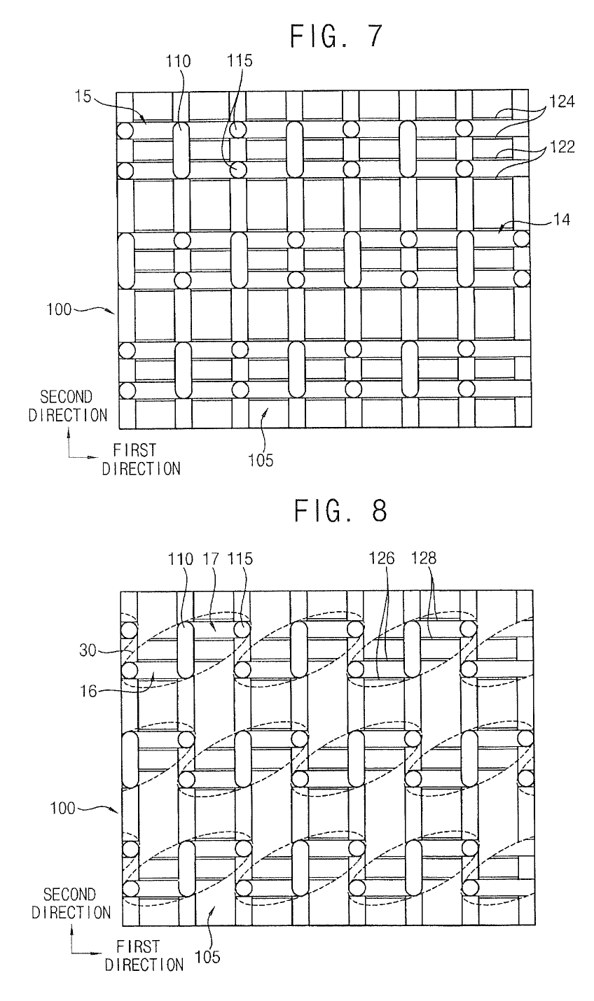

Referring to FIG. 7, a first gate insulation layer 122 is formed on the first nanowire 14, and a second gate insulation layer 124 is formed on the second nanowire 15. The first and second gate insulation layers 122 and 124 may be formed by an atomic layer deposition (ALD) process, a chemical vapor deposition (CVD) process, etc. In an example embodiment, the first and second gate insulation layers 122 and 124 are formed to enclose portions of the first and second nanowires 14 and 15 over the trenches 105 in which the gate lines 140 will be later formed. The first and second gate insulation layers 122 and 124 may be formed using an insulating material having an etching selectivity with respect to an isolation layer 130 (see FIG. 10) that will be formed later. For example, the first and second gate insulation layers 122 and 124 may be formed using an oxide or a nitride.

Alternatively, the first and second gate insulation layers 122 and 124 may be formed on the first and second nanowires 14 and 15 prior to forming the first and second ohmic layers 110 and 115. In this case, portions of the first and second gate insulation layers 122 and 124 on the first and second nanowires 14 and 15 are removed so that the first and second nanowires 14 and 15 may make contact with the first and second ohmic layers 110 and 115.

Referring to FIG. 8, the first and second nanowires 14 and 15 and the first and second gate insulation layers 122 and 124 are partially removed so that first and second nanowire patterns 16 and 17 and first and second gate insulation layer patterns 126 and 128 may be formed.

Particularly, portions of the first and second nanowires 14 and 15 and portions of the first and second gate insulation layers 122 and 124, which are outside of a plurality of first regions 30 defining unit cells, are removed. Accordingly, each of the first regions 30 can include the first and second nanowire patterns 16 and 17 adjacent to each other in the second direction, each of which extends in the first direction, the first and second gate insulation layer patterns 126 and 128, first ohmic layer 110, and a couple of the second ohmic layers 115.

In an example embodiment, a plurality of the unit cells are formed in the first direction to form a unit cell column. Additionally, a plurality of the unit cell columns may be formed in the second direction to form a unit cell array.

An alternate layout of a unit cell is shown in FIG. 9. Referring to FIG. 9, portions of the first and second nanowires 14 and 15 and portions of the first and second gate insulation layers 122 and 124 can be removed by a photolithography process. Each of the second regions 40 may thereby include the first and second nanowire patterns 16 and 17 adjacent to each other in the second direction, each of which extends in the first direction, the first and second gate insulation layer patterns 126 and 128, the first ohmic layer 110, and a couple of the second ohmic layers 115. In the layout of the unit cell shown in FIG. 8, the second ohmic layers 115 in adjacent unit cells in the first direction are disposed in the second direction. In contrast, in the layout of the unit cell shown in FIG. 9, the second ohmic layers 115 in adjacent unit cells in the first direction are not disposed in the second direction. Compared to the unit cell layout shown in FIG. 8, the unit cell layout shown in FIG. 9 may allow a lower degree of integration, but it may better reduce/prevent interference between adjacent unit cells.

Referring to FIG. 10, an isolation layer 130 is formed on portions of the first substrate 100 on which the trenches 105 are not formed. Particularly, a first insulation layer is formed on the first substrate 100 using an insulating material having an etching selectivity with respect to the first and second gate insulation layer patterns 126 and 128, and portions of the first insulation layer on the trenches 105 are removed. Accordingly, a plurality of isolation layers 130 each of which extends in the second direction may be formed. For example, the insulating material may include polymer, an oxide, a nitride, etc.

In FIG. 10, the first and second gate insulation layer patterns 126 and 128 are not shown for the brevity of illustration.

Referring to FIG. 11, a plurality of gate lines 140 are formed on the first substrate 100 to fill up the trenches 105 and to enclose the first and second nanowire patterns 16 and 17 and the first and second gate insulation layer patterns 126 and 128. Accordingly, each of the gate lines 140 may extend in the second direction, and the plurality of gate lines 140 may be spaced apart in the first direction. The gate lines 140 may be formed using a conductive material such as a metal, a metal nitride, polysilicon, etc. Particularly, a first conductive layer can be formed using the conductive material on the first substrate 100 and the isolation layer 130 to enclose the first and second nanowire patterns 16 and 17 and the first and second gate insulation layer patterns 126 and 128 and may fill up the trenches 105. An upper portion of the first conductive layer is planarized so that the gate lines 140 may be formed. The first conductive layer may be formed by an ALD process or a CVD process. The gate lines 140 may enclose the first and second nanowire patterns 16 and 17 so that a GAA type gate structure may be formed. Alternatively, when the trenches 105 are not formed on the first substrate 100, the gate structure may partially enclose the gate insulation layer patterns 126 and 128 and the nanowire patterns 16 and 17 in an Ω-shape.

Referring to FIGS. 12 and 13, a portion of the isolation layer 130 on the first ohmic layer 110 is removed to form a first hole. A first bitline contact 150 can be formed to fill the first hole. The first bitline contact 150 may be formed by forming a second conductive layer on the first ohmic layer 10, the isolation layer 130 and the gate lines 140 to fill up the first hole and planarizing an upper portion of the second conductive layer. The second conductive layer may be formed using a conductive material such as a metal, doped polysilicon, etc. by an ALD process, a CVD process, etc. A plurality of the bitline contacts 150 may be formed correspondingly to the plurality of the first ohmic layers 110.

A first bitline 160 can be formed that directly contacts upper portions of the first bitline contacts 150 and extends in the first direction. The first bitline 160 may be formed by forming a third conductive layer on the isolation layer 130, the gate lines 140 and the first bitline contacts 150 and removing portions of the third conductive layer by a photolithography process. The third conductive layer may be formed using a conductive material such as a metal, doped polysilicon, etc. by a CVD process, a physical vapor deposition (PVD) process, etc.

The first bitline 160 can directly contact the bitline contacts 150 in the plurality of unit cells disposed in the first direction, and thus one bitline 160 may directly contact all first bitline contacts 150 in one unit cell column. According as a plurality of unit cell columns is formed in the second direction, a plurality of the first bitlines 160 each of which is electrically connected to the unit cell column may be formed in the second direction.

In an example embodiment, the first bitline 160 is formed on upper central portions of the first bitline contacts 150. That is, the first bitline 160 may be formed on upper portions of the first bitline contacts 150 under which the first and second nanowire patterns 16 and 17 are not formed.

Referring to FIG. 14, a second insulation layer 170 is formed on the isolation layer 130 and the gate lines 140 to cover the first bitline contacts 150 and the first bitline 160. The second insulation layer 170 may be formed using an oxide or a nitride by a CVD process or a PVD process.

Referring to FIGS. 15 and 16, portions of the isolation layer 130 and portions of the second insulation layer 170 on or over the second ohmic layer 115 are removed to form a second hole, and a first capacitor contact 180 filling up the second hole is formed. The first capacitor contact 180 may be formed by depositing a fourth conductive layer on the second ohmic layer 115 and the second insulation layer 170 to fill up the second hole, and by planarizing an upper portion of the second conductive layer. The fourth conductive layer may be formed using a metal, doped polysilicon, etc. by an ALD process, a CVD process, etc. A plurality of the first capacitor contacts 180 may be formed correspondingly to the plurality of the second ohmic layer 115.

A first capacitor 190 is formed to make contact with the first capacitor contact 180. The first capacitor 190 may be formed by a conventional method. Particularly, a third insulation layer (not shown) is formed on the second insulation layer 170, and a third hole exposing the first capacitor contact 180 is formed. A first electrode (not shown), a dielectric layer (not shown) and a second electrode (not shown) are sequentially formed on the first capacitor contact 180 and the third insulation layer to fill up the third hole. Upper portions of the second electrode, the dielectric layer and the first electrode are removed to form the first capacitor 190, and the third insulation layer is removed. Cylindrical capacitors are shown in FIG. 15, however, the present invention is not limited to the cylindrical capacitors, and various types of capacitors may be included within the scope of the present invention.

By performing the above-described processes, the semiconductor device in accordance with some example embodiments may be manufactured. In this method, after nanowires are formed using optimum materials for channels, which may have different conductive types, the nanowires are alternately disposed on a substrate. Then, gate structures, bitlines and capacitors are formed. Thus, the semiconductor device having good channel characteristics may be easily manufactured.

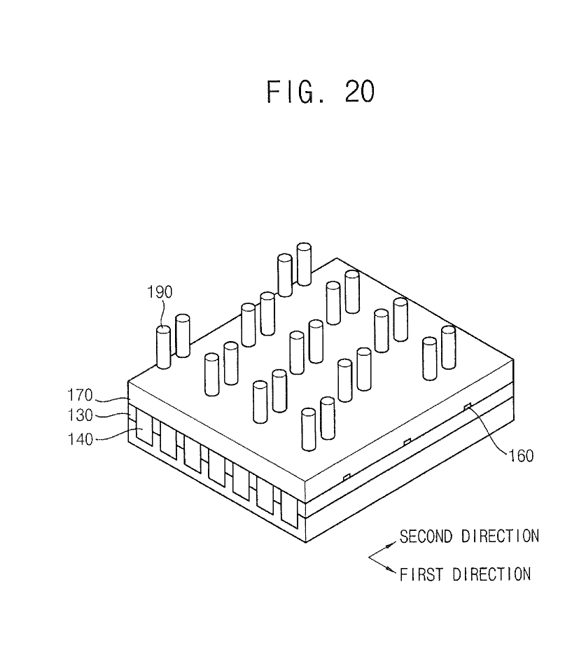

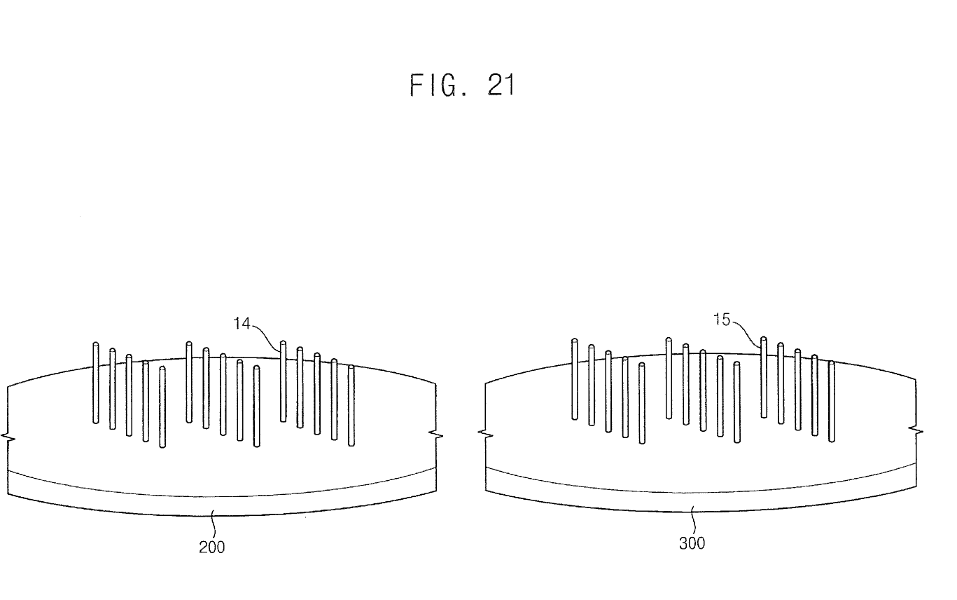

FIGS. 17 and 20 are perspective views illustrating methods of manufacturing semiconductor devices in accordance with some other example embodiments. FIG. 18 is an enlarged view of first and second nanowires 34 and 35 in FIG. 17. FIG. 19 is a plan view illustrating the above methods of manufacturing the semiconductor device. The methods illustrated with reference to FIGS. 17 to 20 are substantially the same as or similar to the methods illustrated with reference to FIGS. 1 to 16 except that after the first and second nanowires 14 and 15 are grown on the second and third substrates 200 and 300, respectively, third and fourth gate insulation layers 24 and 25 are formed on the first and second nanowires 14 and 15, respectively, before disposing the first and second nanowires 14 and 15 on the first substrate 100. Thus, like numerals refer to like elements, and repetitive explanations are omitted here.

Referring to FIGS. 17 and 18, the first and second nanowires 14 and 15 are grown on the second and third substrates 200 and 300, respectively, by a CVD process using a nanowire source gas.

The third and fourth gate insulation layers 24 and 25 enclosing the first and second nanowires 14 and 15, respectively, are formed. Thus, a first nanowire structure 34 including the first nanowire 14 and the third gate insulation layer 24 may be formed, and a second nanowire structure 35 including the second nanowire 15 and the fourth gate insulation layer 25 may be formed. The third and fourth gate insulation layers 24 and 25 may be formed using an insulating material such as an oxide or a nitride, which has an etching selectivity with respect to the isolation layer 130. The third and fourth gate insulation layers 24 and 25 may be formed by a CVD process or an ALD process.

Referring to FIG. 19, processes similar to those illustrated with reference to FIGS. 3 to 7 are performed. However, in these methods, after the first and second nanowire structures 34 and 35 including the third and fourth gate insulation layers 24 and 25 are formed on the first substrate 100, the first and second ohmic layers 110 and 115 are formed. Thus, an additional process for removing portions of the third and fourth gate insulation layers 24 and 25 are performed so that the first and second ohmic layers 110 and 115 may make contact with the first and second nanowires 14 and 15, respectively.

Referring to FIG. 20, processes similar to those illustrated with reference to FIGS. 8 to 16 are performed to complete the semiconductor device.

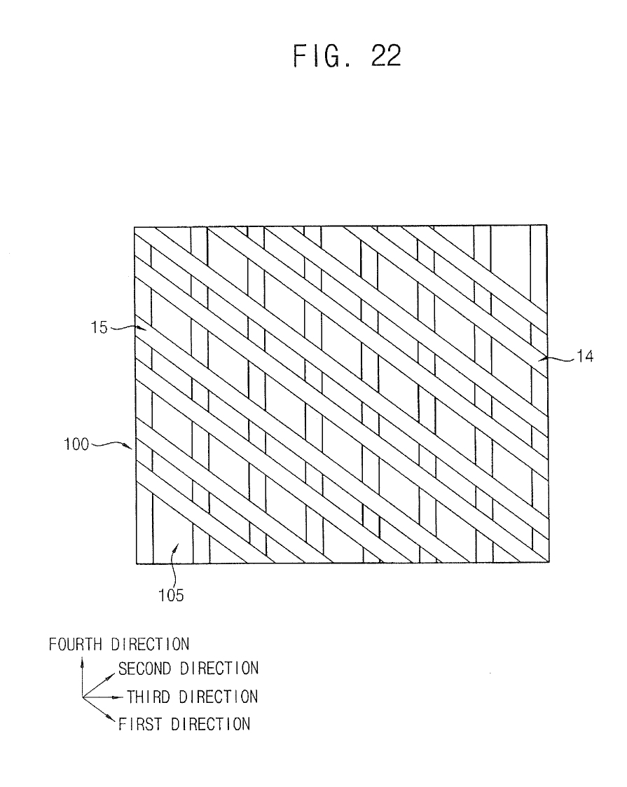

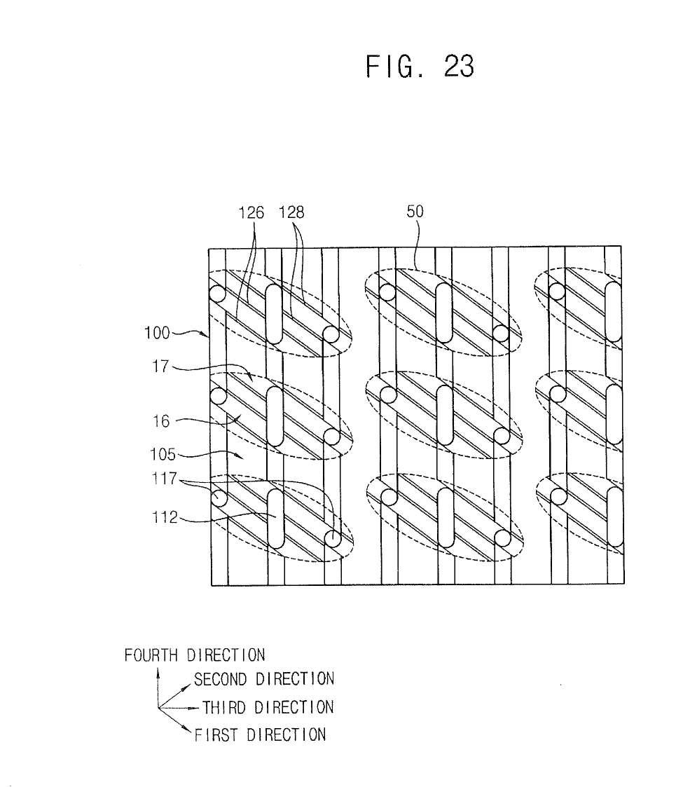

FIGS. 21, 24 and 25 are perspective views illustrating methods of manufacturing a semiconductor device in accordance with still other example embodiments. FIGS. 22 and 23 are plan views illustrating the above methods. The methods illustrated with reference to FIGS. 21 to 25 are substantially the same as or similar to the methods illustrated with reference to FIGS. 1 to 16 except that the first and second nanowires 14 and 15 do not extend in a direction perpendicular to that in which trenches 105 or gate lines 140 extend. The two directions may make an acute angle with each other. Thus, like numerals refer to like elements, and repetitive explanations are omitted here.

Referring to FIG. 21, the first and second nanowires 14 and 15 are grown on the second and third substrates 200 and 300, respectively, by a CVD process using a nanowire source gas.

Referring to FIG. 22, the first and second nanowires 14 and 15 are disposed on the first substrate 100 on which a plurality of trenches 105 is formed in a third direction. Each of the trenches 105 extends in a fourth direction perpendicular to the third direction. Particularly, the first and second nanowires 14 and 15 each of which extends in a first direction are alternately disposed on the first substrate 100 in a second direction perpendicular to the first direction. Accordingly, the first and second nanowires 14 and 15 may be disposed in the second direction on the first substrate 100 in the sequence of a first nanowire 14, a second nanowire 15, a first nanowire 14, a second nanowire 15, and so on. The second direction may not be perpendicular to the third direction, but make an acute angle with the third direction or the fourth direction.

Referring to FIG. 23, processes similar to those illustrated with reference to FIGS. 7 to 9 are performed to form a plurality of unit cells defined within a plurality of third regions 50. However, the unit cells or a plurality of unit cell columns each of which includes the unit cells may be disposed on the first substrate 100 in a direction different from that in which the unit cells or the unit cell columns shown in FIGS. 7 to 9.

Particularly, each of the first and second nanowire patterns 16 and 17 in the unit cell does not extend in the third direction that is perpendicular to the fourth direction. That is, each of the first and second nanowire patterns 16 and 17 does not extend perpendicularly to a direction in which each of the trenches 105 extends, but extends in the first direction making an acute angle with the direction in which each of the trenches 105 extends. Thus, the first and second nanowire patterns 16 and 17 may be spaced apart in the second direction perpendicular to the first direction.

A plurality of unit cells adjacent to each other in the first direction does not form a unit cell column, however, a plurality of unit cells adjacent to each other in the third direction forms a unit cell column, and a second bitline 165 that will be formed later is commonly electrically connected to the unit cells included in the unit cell column.

In FIG. 23, a plurality of third ohmic layers 112 is formed in the fourth direction and a plurality of fourth ohmic layers 117 is also formed in the fourth direction, however, the present invention is not limited thereto. That is, the third ohmic layers 112 and the fourth ohmic layers 117 may be alternately formed in the fourth direction.

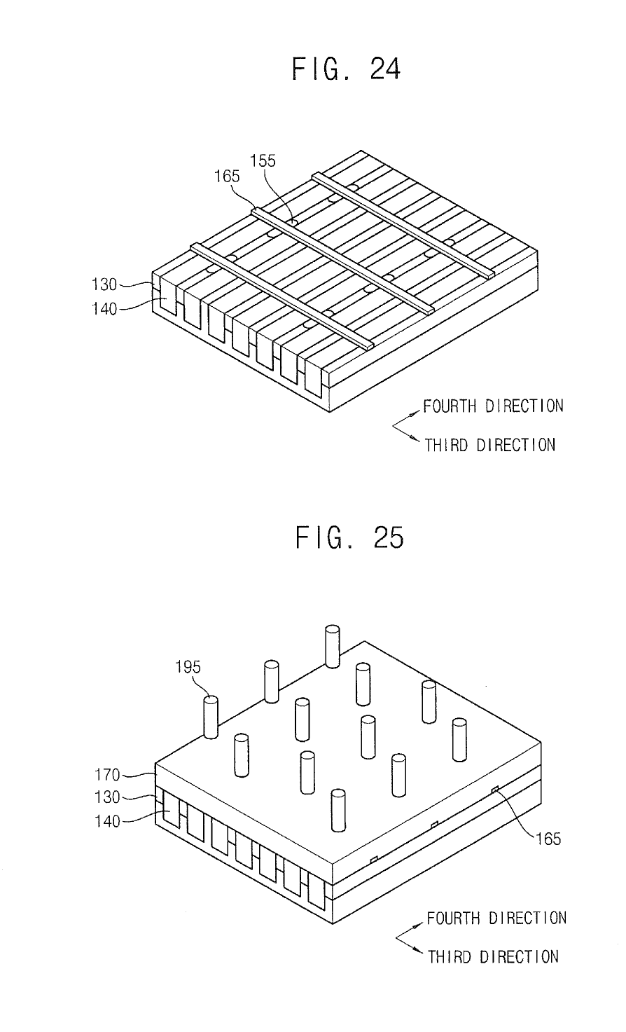

Referring to FIG. 24, processes similar to those illustrated with reference to FIGS. 10 to 13 are performed, so that the isolation layer 130, the gate lines 140, a second bitline contact 155 and the bitline 165 are formed.

However, each of the isolation layers 130 and the gate lines 140 are formed to extend in the fourth direction, and each of the second bitlines 165 is formed to extend in the third direction.

The second bitline contact 155 is formed to make contact with the third ohmic layer 112, and the second bitline 165 is formed to make contact with upper central portions of the second bitline contacts 155.

Referring to FIG. 25, processes similar to those illustrated with reference to FIGS. 14 to 16 are performed to form the second insulation layer 170, a second capacitor contact (not shown) and a second capacitor 195. The second capacitor contact is formed to make contact with the fourth ohmic layer 117, and the second capacitor 195 is formed to make contact with the second capacitor contact.

Various semiconductor devices may thereby be manufactured using the above-described methods.

According to some example embodiments, nanowires having different conductive types may be formed using optimum materials for channels, the nanowires can be alternately disposed on a substrate, and gate structures, bitlines and capacitors are formed. The resulting semiconductor devices may have improved channel characteristics and/or the associated manufacturing processes may be simplified.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of manufacturing a semiconductor device, the method comprising:
alternately forming first nanowires and second nanowires on a first substrate spaced apart in a second direction that is parallel to an adjacent major surface of the substrate, each of the first and second nanowires extending in a first direction that is perpendicular to the second direction, wherein the first and second nanowires are doped with first and second conductivity type dopants, respectively; and
forming a plurality of gate lines that are at least partially disposed within the first substrate, that are spaced apart in a third direction, that extend in a fourth direction that is perpendicular to the third direction, and that partially enclose the first and second nanowires.

2. The method of claim 1, further comprising removing portions of the first and second nanowires to form a plurality of first nanowire patterns and a plurality of second nanowire patterns, respectively,
wherein the gate lines partially enclose the first and second nanowire patterns.

3. The method of claim 2, wherein a plurality of unit cells are defined on the first substrate, each of the unit cells including a plurality of the first and second nanowire patterns spaced apart in the second direction.

4. The method of claim 3, wherein a plurality of the unit cells are disposed in the fourth direction to define a unit cell column, and a plurality of the unit cell columns are spaced apart in the third direction to define a unit cell array.

5. The method of claim 4, further comprising:
forming a bitline that is electrically connected to the unit cells within each of the unit cell columns; and
forming a plurality of capacitors electrically connected to the unit cells, respectively.

6. The method of claim 5, further comprising:
forming a plurality of bitline contacts that electrically connect the bitline to the unit cells; and
forming a plurality of capacitor contacts that electrically connect the capacitors to the unit cells, respectively.

7. The method of claim 6, further comprising:
forming a plurality of first ohmic layers that directly contact the bitline contacts, respectively, the first ohmic layers extending to directly contact the first and second nanowire patterns in each unit cell; and
forming a plurality of second ohmic layers that directly contact the capacitor contacts, respectively, the second ohmic layers making contact with the first and second nanowire patterns, respectively, in each unit cell.

8. The method of claim 1, further comprising forming a gate insulation layer on each of the first and second nanowires.

9. The method of claim 8, wherein forming the gate insulation layer is performed prior to disposing the first and second nanowires on the first substrate.

10. The method of claim 1, wherein the third direction is the same as the second direction.

11. The method of claim 1, wherein the third direction makes an acute angle with the first direction.

12. The method of claim 1, wherein the first conductivity type is a p-type and the second conductivity type is an n-type.

13. The method of claim 12, wherein the first nanowires are formed to include germanium and the second nanowires are formed to include gallium arsenide (GaAs).

14. The method of claim 1, wherein formation of the first and second nanowires comprises:
applying catalyst particles onto second and third substrates;
depositing a nanowire source gas onto the second and third substrates to grow the first and second nanowires from the second and third substrates, respectively; and
moving the first and second nanowires to be alternately disposed on the first substrate spaced apart in the second direction.

15. The method of claim 1, further comprising:
forming a plurality of trenches on the first substrate spaced apart in the fourth direction, each of the trenches extending in the third direction; and
forming the gate lines within and to fill the trenches.

16. The method of claim 1, wherein alternately disposing the first and second nanowires on the first substrate comprises:
disposing the first nanowires on the first substrate spaced apart in the second direction; and
disposing the second nanowires on the first substrate spaced apart in the second direction in spaces between adjacent pairs of the first nanowires.

17-25. (canceled)
